(19) United States
(12) Patent Application Publication
(10) Pub. No.: US 2026/0356094 A1
(43) Pub. Date: Nov. 12, 2026

(54) LIQUID DISCHARGE HEAD, LIQUID DISCHARGE APPARATUS, INKJET PRINTER, THREE-DIMENSIONAL FABRICATING APPARATUS, AND ELECTRIC CIRCUIT MANUFACTURING APPARATUS

(71) Applicants: Masahiro KURI, Kanagawa (JP); Akio YOSHITA, Kanagawa (JP); Takuma HIRABAYASHI, Tokyo (JP)

(72) Inventors: Masahiro KURI, Kanagawa (JP); Akio YOSHITA, Kanagawa (JP); Takuma HIRABAYASHI, Tokyo (JP)

(21) Appl. No.: 19/663,320

(22) Filed: Apr. 30, 2026

(30) Foreign Application Priority Data
May 7, 2025 (JP) 2025-077246

(51) Int. Cl. B41J 2/14; H10N 30/50; H10N 30/87; H10N 39/00

(52) U.S. Cl. CPC B41J 2/14233; H10N 30/501; H10N 30/871; H10N 39/00; B41J 2002/14258

(57) ABSTRACT

A liquid discharge head includes: a nozzle plate having multiple nozzles; a channel substrate having multiple pressure chambers respectively communicating with the multiple nozzles, the multiple pressure chambers arrayed in a array direction of the channel substrate; a diaphragm facing the multiple pressure chambers; and a piezoelectric member to vibrate the diaphragm to discharge liquid in the multiple pressure chambers from the multiple nozzles in a discharge direction perpendicular to the array direction, wherein the piezoelectric member includes: a first individual electrode over the diaphragm in a stacking direction opposite to the discharge direction; a first piezoelectric body over the first individual electrode in the stacking direction; a first common electrode over the first piezoelectric body in the stacking direction; a second piezoelectric body over the first common electrode in the stacking direction; and a second individual electrode over the second piezoelectric body in the stacking direction.

### CROSS-REFERENCE TO RELATED APPLICATION

This patent application is based on and claims priority pursuant to 35 U.S.C. § 119(a) to Japanese Patent Application No. 2025-077246, filed on May 7, 2025, in the Japan Patent Office, the entire disclosure of which is hereby incorporated by reference herein.

### BACKGROUND

### Technical Field

The present embodiment relates to a liquid discharge head, a liquid discharge apparatus, an inkjet printer, a three-dimensional fabricating apparatus, and an electric circuit manufacturing apparatus.

### Related Art

In recent years, there has been a demand for a liquid discharge head capable of discharging a high-viscosity liquid, because of a variety of types of liquid to be discharged by the liquid discharge head and applications of the liquid discharge head.

To cause a liquid discharge head to discharge a high-viscosity liquid, the discharge speed and the amount of the liquid to be discharged by the liquid discharge head are increased. In the case of a liquid discharge head that vibrates a thin film with a piezoelectric body to discharge liquid, the discharge speed and the amount of the liquid to be discharged can be increased by stacking the piezoelectric bodies.

For example, a lower electrode, one piezoelectric layer, an individual electrode, the other piezoelectric layer, and an upper electrode are stacked in this order from the pressure chamber side, and multiple piezoelectric bodies are provided. The lower electrode and the upper electrode are common electrodes.

### SUMMARY

The present disclosure described herein provides a liquid discharge head including: a nozzle plate having multiple nozzles; a channel substrate having multiple pressure chambers respectively communicating with the multiple nozzles, the multiple pressure chambers arrayed in a array direction of the channel substrate; a diaphragm facing the multiple pressure chambers; and a piezoelectric member to vibrate the diaphragm to discharge liquid in the multiple pressure chambers from the multiple nozzles in a discharge direction perpendicular to the array direction, wherein the piezoelectric member includes: a first individual electrode over the diaphragm in a stacking direction opposite to the discharge direction; a first piezoelectric body over the first individual electrode in the stacking direction; a first common electrode over the first piezoelectric body in the stacking direction; a second piezoelectric body over the first common electrode in the stacking direction; and a second individual electrode over the second piezoelectric body in the stacking direction, and the first common electrode extends across the multiple pressure chambers in the array direction.

### BRIEF DESCRIPTIONS OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a perspective view of an example of a configuration of a head module including a liquid discharge head;

FIG. 2 is a cross-sectional view of the liquid discharge head in FIG. 1;

FIG. 3 is a cross-sectional view of a stack configuration of a piezoelectric member;

FIG. 4 is a plan view of the piezoelectric member and a channel substrate;

FIG. 5 is a cross-sectional view of a modification of the piezoelectric member;

FIG. 6 is a cross-sectional view of another modification of the piezoelectric member;

FIG. 7 is a view of an entire configuration of a liquid discharge apparatus;

FIG. 8 is a diagram illustrating a control system of the liquid discharge apparatus in FIG. 7;

FIG. 9 is a plan view illustrating an example configuration of a line head unit;

FIG. 10 is a plan view illustrating an example configuration of a serial head unit; and

FIG. 11 is a schematic diagram of a different example of a liquid discharge apparatus.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

The following is a description of the present embodiment, with reference to the drawings. Note that identical or corresponding portions are given identical reference numerals, and redundant descriptions are summarized or omitted accordingly.

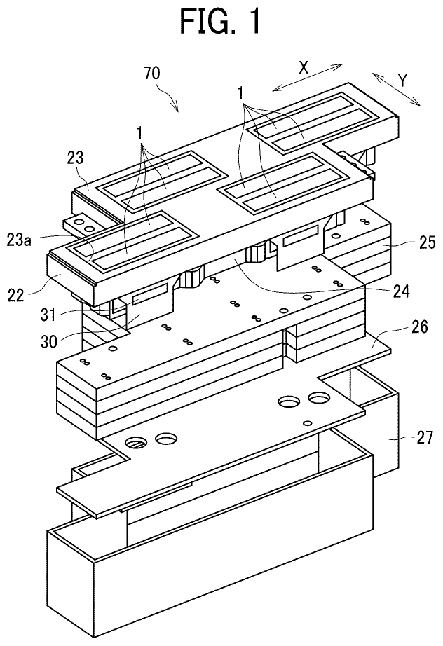

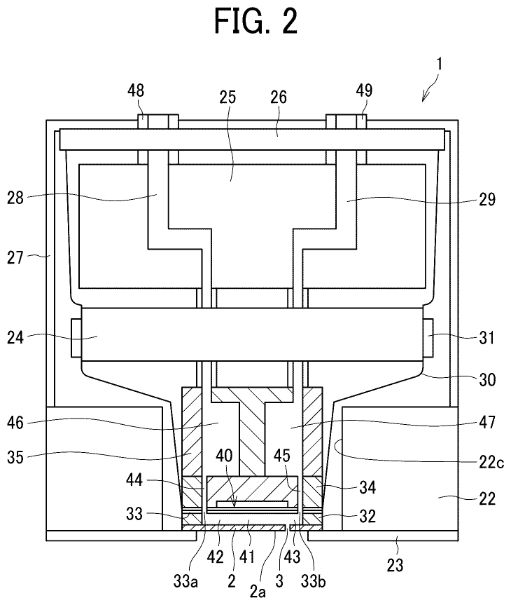

Next, an example of a configuration of a head module including a liquid discharge head according to the present embodiment will be described with reference to FIGS. 1 and 2.

FIG. 1 is an exploded perspective view of the head module, and FIG. 2 is a cross-sectional view of the head module illustrated in FIG. 1 in a transverse direction of the head module (the direction Y indicated by an arrow Y in FIG. 1).

As illustrated in FIG. 1, a head module 70 includes multiple liquid discharge heads 1, a base 22, a cover 23, a heat dissipator 24, a manifold 25, a printed circuit board (PCB) 26, and a module case 27.

The base 22 as a holder holds the multiple liquid discharge heads 1. To attach a liquid discharge head 1 to the base 22, the liquid discharge head 1 is first inserted into an opening 22c (see FIG. 2) formed in the base 22. The liquid discharge head 1 is then bonded to the cover 23 bonded to the base 22. The cover 23 has holes 23a corresponding to the respective liquid discharge heads 1, and a peripheral area of each liquid discharge head 1 is bonded to an edge of the corresponding hole 23a. The liquid discharge heads 1 are then fixed to the base 22 with screws. Specifically, a common channel substrate 35 (see FIG. 2) has flanges on the front side and the back side in the longitudinal direction (direction orthogonal to the surface of the paper on which FIG. 2 is drawn) of the liquid discharge heads 1, and the flanges are fastened to the base 22 with screws. Thus, the base 22 holds the common channel substrate 35 to fix the liquid discharge heads 1. The structure for attaching the liquid discharge heads 1 to the base 22 is not limited to this structure, and the liquid discharge heads 1 may be attached to the base 22 by adhesion, caulking, or the like.

The base 22 is preferably made of a material having a small linear expansion coefficient. Examples of the material having a small linear expansion coefficient include a 42-alloy, which is an alloy of iron with nickel, and an invar material. With the base 22 made of such a material, even when the temperature of the base 22 is raised by heat generated by the liquid discharge heads 1, the amount of expansion of the base 22 is small, and thus, positional deviation of the multiple nozzles is unlikely to occur. As a result, positional deviation of the discharged ink can be reduced. Further, a nozzle plate 2 and a diaphragm 33 that will be described later (see FIG. 2) are formed with a silicon single crystal substrate, and the linear expansion coefficient of the nozzle plate 2 and the diaphragm 33 is set to a value substantially the same as that of the base 22, so that positional deviation of the multiple nozzles due to thermal expansion can be further reduced.

As illustrated in FIG. 2, each liquid discharge head 1 includes a nozzle plate 2, a channel substrate 32, a diaphragm 33, a piezoelectric member 40, a holding substrate 34, the common channel substrate 35 as a frame member, and the like. The nozzle plate 2 is provided with multiple nozzles 3. The channel substrate 32 has wall portions and a pressure chamber 41 communicating with the multiple nozzles 3. The wall portions form the pressure chamber 41 with the diaphragm 33. The diaphragm 33, the holding substrate 34, and the common channel substrate 35 are stacked in this order.

In addition to the pressure chamber 41, supply-side individual channels 42 communicating with the pressure chamber 41, and collection-side individual channels 43 communicating with the pressure chamber 41 are formed in the channel substrate 32. The holding substrate 34 defines supply-side intermediate individual channels 44 and collection-side intermediate individual channels 45. The supply-side intermediate individual channels 44 communicate with the supply-side individual channels 42 via openings 33a of the diaphragm 33, respectively. The collection-side intermediate individual channels 45 communicate with the collection-side individual channels 43 via openings 33b of the diaphragm 33, respectively.

The common channel substrate 35 (that is, the frame member) defines a supply-side common channel 46 and a collection-side common channel 47. The supply-side common channel 46 communicates with the supply-side intermediate individual channels 44. The collection-side common channel 47 communicates with the collection-side intermediate individual channels 45. The supply-side common channel 46 communicates with a supply port 48 via a channel 28 of the manifold 25.

The collection-side common channel 47 communicates with a collection port 49 via another channel 29 of the manifold 25.

The PCB 26 and the piezoelectric member 40 of the liquid discharge head 1 are connected via a flexible wiring board 30. A driver integrated circuit (IC) 31 is mounted on the flexible wiring board 30.

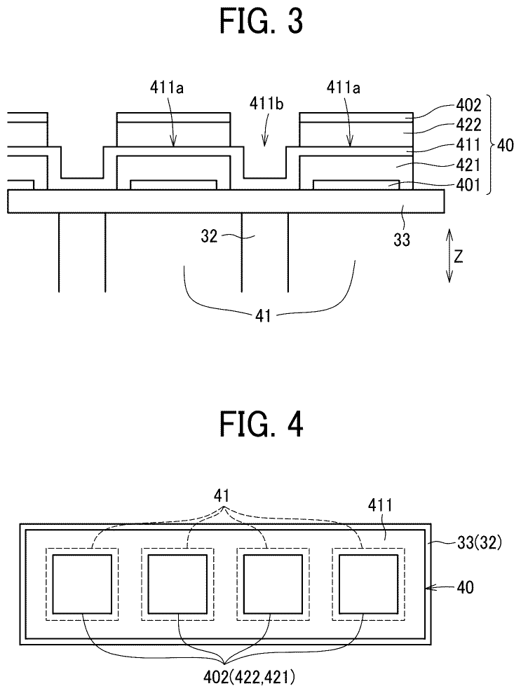

Next, a more detailed configuration of the piezoelectric member 40 will be described with reference to FIGS. 3 and 4. FIG. 3 is a cross-sectional view of the stack configuration of the piezoelectric member, and FIG. 4 is a plan view of the piezoelectric member and the channel substrate. Although the supply-side individual channels 42, the collection-side individual channels 43 (see FIG. 2), and the like adjacent to the pressure chamber 41 are not illustrated in FIG. 4, these and the pressure chamber 41 are connected by channels or fluid resistance portions thinner than the supply-side individual channels 42 and the collection-side individual channels 43.

As illustrated in FIG. 3, the piezoelectric member 40 includes a first individual electrode 401, a first piezoelectric body 421, a first common electrode 411, a second piezoelectric body 422, and a second individual electrode 402 that are stacked in this order from the side of the pressure chamber 41. The phrase “stacked in this order” includes a case where another layer such as an insulating layer is interposed between them. The vertical direction Z in FIG. 3 is the stacking direction of the respective layers of the piezoelectric member 40, and is also referred to simply as the stacking direction. Also, the vertical direction in FIG. 3 is also referred to simply as the upward direction or the downward direction, but does not necessarily mean a direction opposite to the direction of gravitational force in the actual liquid discharge heads or a liquid discharge apparatus.

A stacked portion in which the first individual electrode 401 and the like are stacked is provided for each pressure chamber 41. That is, the first individual electrode 401, the first piezoelectric body 421, the second piezoelectric body 422, and the second individual electrode 402 are provided directly above each pressure chamber 41 so as to face the pressure chamber 41, as viewed in the stacking direction. The first common electrode 411 forms part of these stacked portions, and includes stacked portions 411a stacked on the first piezoelectric bodies 421, and bridges 411b connecting the stacked portions 411a. That is, the first common electrode 411 is provided over multiple pressure chambers 41. Each bridge 411b includes a portion that extends in the horizontal direction in FIG. 3 and bridges the stacked portions 411a at the same height as the first individual electrodes 401 in the stacking direction, and a portion that extends in the stacking direction and connects the former portion and the stacked portions 411a.

The first piezoelectric body 421 is interposed between the first individual electrode 401 and the bridge 411b, so that the first individual electrode 401 and the bridge 411b are not in contact with each other. This prevents short-circuiting due to conduction between the first individual electrode 401 and the first common electrode 411.

As illustrated in FIG. 4, the first common electrode 411 is provided over multiple pressure chambers 41 as viewed in the stacking direction, which is the direction of view in FIG. 4. The multiple pressure chambers 41 are arrayed in an array direction. The array direction may be along a longitudinal direction of the channel substrate 32 orthogonal to the discharge direction of the liquid from the nozzles 3. However, the array direction may be along a transverse direction of the channel substrate 32 orthogonal to the discharge direction and the longitudinal direction.

Also, the first common electrode 411 is preferably provided over (while facing) the entire regions of the multiple second piezoelectric bodies 422 as viewed in the stacking direction, and, in particular, is preferably provided over (while facing) the entire regions of all the second piezoelectric bodies 422. The first common electrode 411 is provided over the entire regions of all the first piezoelectric bodies 421 as viewed in the stacking direction. In the present embodiment, the ranges in which the second individual electrode 402, the first piezoelectric body 421, and the second piezoelectric body 422 are provided coincide with each other as viewed in the stacking direction, but it is not necessarily limited to this. Further, as illustrated in FIG. 4, the common electrode is not necessarily provided over the entire regions of all the second piezoelectric bodies 422 and the first piezoelectric bodies 421 as viewed in the stacking direction, and may be provided over some of those regions.

As described above, in the piezoelectric member 40 of the present embodiment, multiple piezoelectric bodies 421 and 422 are provided, and are sandwiched between the first individual electrode 401 and the first common electrode 411, or between the first common electrode 411 and the second individual electrode 402. In this manner, as multiple piezoelectric bodies are provided, and a layer configuration capable of applying a voltage to each of the piezoelectric bodies is formed, the pressure to be applied to the pressure chambers 41 can be increased, and the discharge speed and the amount of the liquid to be discharged by the liquid discharge heads can be increased.

The first common electrode 411 is provided between the first piezoelectric body 421 and the second piezoelectric body 422. Accordingly, the first common electrode 411 can be shared between the side of the first piezoelectric body 421 and the side of the second piezoelectric body 422. Thus, the second common electrode and the insulating layer between the electrodes on the center side can be omitted, and the layer configuration of the piezoelectric member 40 can be reduced. As a result, a decrease in the number of manufacturing steps, and cost reduction can be achieved. Further, as the second piezoelectric body 422 is disposed above the first common electrode 411 (on the opposite side from the pressure chamber) (and any other common electrode is not disposed above the second piezoelectric body 422), the shape of the second piezoelectric body 422 is not limited by the first common electrode 411 disposed over the multiple pressure chambers 41. Thus, the efficiency of deformation of the second piezoelectric body 422 at a time of voltage application can be increased, and the discharge speed and the amount of the liquid to be discharged by the liquid discharge head can be increased.

Furthermore, as the first common electrode 411 is provided over multiple stacked portions by the bridges 411b, or, in other words, the first common electrode 411 is provided over multiple pressure chambers 41, the process of forming the first common electrode 411 can be simplified. That is, in a case where multiple first common electrodes 411 are provided separately for the respective portions corresponding to the stacked portions 411a, the portions of the bridges 411b is removed by performing etching or the like after forming the layer of the first common electrodes 411 as illustrated in FIG. 3. Accordingly, with the configuration of the present embodiment, it is possible to achieve a decrease in the number of manufacturing steps and a reduction in the cost of the piezoelectric member 40.

Next, modifications of the layer configuration of the piezoelectric member will be described one by one.

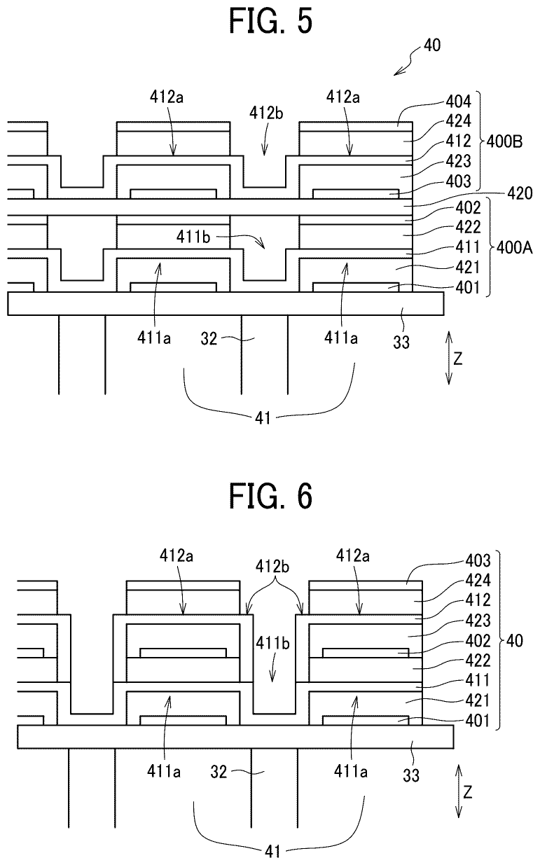

A piezoelectric member 40 illustrated in FIG. 5 includes a first piezoelectric unit 400A, a second piezoelectric unit 400B, and an insulating layer 420.

Each piezoelectric unit has the layer configuration described above in the embodiment illustrated in FIG. 3. Specifically, the first piezoelectric unit 400A includes a first individual electrode 401, a first piezoelectric body 421, a first common electrode 411, a second piezoelectric body 422, and a second individual electrode 402 that are stacked in this order.

The second piezoelectric unit 400B includes a third individual electrode 403, a third piezoelectric body 423, a second common electrode 412, a fourth piezoelectric body 424, and a fourth individual electrode 404 that are stacked in this order. In the present embodiment, four piezoelectric bodies are stacked in this manner.

The first common electrode 411 and the second common electrode 412 have bridges 411b and 412b that bridge stacked portions 411a and 412a, respectively. By the bridges 411b and 412b, the first common electrodes 411 and the second common electrode 412 are arranged over multiple pressure chambers 41 as viewed in the stacking direction, and are arranged, for example, as illustrated in FIG. 4 of the above-described embodiment. Further, an insulating layer 420 is provided between the first piezoelectric unit 400A and the second piezoelectric unit 400B.

Although a case where two piezoelectric units are provided in the stacking direction has been described in the present modification, three or more piezoelectric units may be provided. For example, with a natural number m=1, 2, . . . , n being set, a piezoelectric member 40 includes piezoelectric units from the first piezoelectric unit to the n-th piezoelectric unit, and has an insulating layer between each two adjacent piezoelectric units. An m-th piezoelectric unit includes a (2m−1)th individual electrode, a (2m−1)th piezoelectric body, an m-th common electrode, a 2m-th piezoelectric body, and a 2m-th individual electrode stacked in this order from the side of the pressure chamber 41 in the stacking direction of the piezoelectric member 40.

Next, a piezoelectric member 40 of a modification illustrated in FIG. 6 includes a first individual electrode 401, a first piezoelectric body 421, a first common electrode 411, a second piezoelectric body 422, a second individual electrode 402, a third piezoelectric body 423, a second common electrode 412, a fourth piezoelectric body 424, and a third individual electrode 403 that are stacked in this order from the side of the pressure chamber 41.

In the present modification, four piezoelectric bodies are stacked in the piezoelectric member 40, as in the modification in FIG. 5 described above. As a difference from the modification in FIG. 5, the bridge 411b of the first common electrode 411 and the bridge 412b of the second common electrode 412, which are common electrodes, are electrically connected. Thus, in the modification in FIG. 6, the insulating layer 420 provided between the second individual electrode 402 and the third individual electrode 403 in FIG. 5 can be omitted, and the second individual electrode 402 and the third individual electrode 403 in FIG. 5 are replaced with the second individual electrode 402, which is an individual electrode.

The first common electrode 411 has the bridge 411b that bridges stacked portions 411a. With the bridge 411b, the first common electrode 411 is disposed over multiple pressure chambers 41 as viewed in the stacking direction, and is disposed, for example, as illustrated in FIG. 4 of the above-described embodiment. The bridge 412b of the second common electrode 412 is then electrically connected to the bridge 411b.

The piezoelectric member 40 of the modification in FIG. 6 presents an example of a configuration in which four piezoelectric bodies are provided. However, a piezoelectric member 40 may have a configuration including an even number of piezoelectric bodies, such as six or more piezoelectric bodies. For example, where m is a natural number m=1, 2, . . . , n (n being an integer of 3 or greater), an m-th piezoelectric unit is a unit in which a (2m−1)th piezoelectric body, an m-th common electrode, a 2m-th piezoelectric body, and an (m+1)th individual electrode are stacked in this order from the side of the pressure chamber 41 in the stacking direction of the piezoelectric member 40. In this case, the piezoelectric member 40 may include a first individual electrode and the respective piezoelectric units from the first piezoelectric unit to the n-th piezoelectric unit from the side of the pressure chamber 41 in the stacking direction.

At least at any m, the m-th common electrode and the (m+1)th common electrode are electrically connected by a bridge, like the first common electrode 411 and the second common electrode 412 in FIG. 6. With such a configuration, the piezoelectric member 40 having 2m piezoelectric bodies can be formed.

In the modifications in FIGS. 5 and 6, a layer configuration that includes four or more piezoelectric bodies and is capable of applying voltage is formed, so that the pressure to be applied to the pressure chamber 41 can be made higher than that in the embodiment in FIG. 3, and the discharge speed and the amount of the liquid to be discharged by the liquid discharge head can be increased. As the uppermost piezoelectric body is not constrained by the common electrode and excels in deformation efficiency, the discharge speed and the amount of the liquid to be discharged by the liquid discharge head can be increased.

The common electrode at the center is shared between the upper and lower individual electrodes, so that the number of layers in the piezoelectric member 40 can be reduced, and a decrease in the number of manufacturing steps and cost reduction can be achieved. The common electrode is provided over the multiple pressure chambers 41, and thus, it is possible to reduce the number of manufacturing steps and lower the cost of the piezoelectric member 40. In the modification in FIG. 6, in particular, the number of stacked layers can be made smaller as compared with that in the modification in FIG. 5, and, in particular, it is possible to achieve a decrease in the number of manufacturing steps and lower the cost of the piezoelectric member 40.

In the modifications in FIGS. 5 and 6, the configuration of the embodiment in FIG. 3 can be adopted as appropriate. For example, the common electrode can be disposed in the entire regions of all the piezoelectric bodies as viewed in the stacking direction.

A liquid discharge apparatus including the liquid discharge head described above, or a head module including multiple liquid discharge heads will be described below.

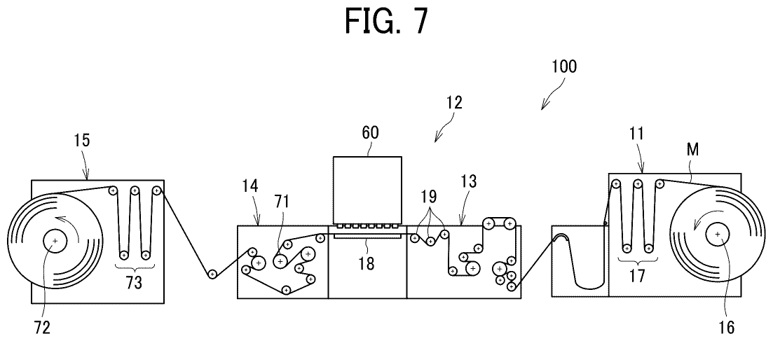

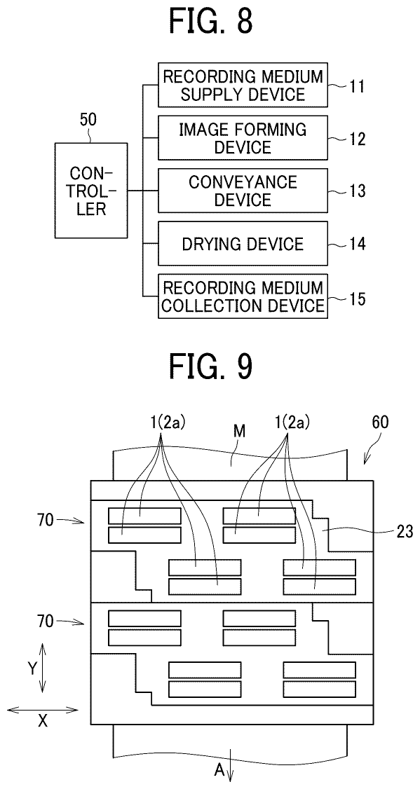

As illustrated in FIG. 7, an image forming apparatus 100 as a liquid discharge apparatus according to the present embodiment includes a recording medium supply device 11 that supplies a recording medium M for image formation, an image forming device 12 that forms an image on the recording medium M, a conveyance device 13 that conveys the recording medium M to the image forming device 12, a drying device 14 that dries the recording medium M, and a recording medium collection device 15 that collects the recording medium M on which the image is formed. The image forming apparatus 100 according to the present embodiment further includes a controller 50 (see FIG. 8) that controls the recording medium supply device 11, the image forming device 12, the conveyance device 13, the drying device 14, and the recording medium collection device 15.

The recording medium supply device 11 includes a supply roller 16 around which the long recording medium M is wound in a roll-like shape, and a tension adjustment mechanism 17 that adjusts the tension to be applied to the recording medium M. The supply roller 16 is rotatable in the direction indicated by an arrow illustrated in FIG. 7, and the recording medium M is fed from the supply roller 16 as the supply roller 16 rotates. The tension adjustment mechanism 17 includes multiple rollers between which the recording medium M is stretched to apply tension to the recording medium M. Some of the multiple rollers move to adjust the tension of the recording medium M, and the recording medium M is fed from the supply roller 16 with a constant tension.

The image forming device 12 includes a head unit 60 as a liquid discharge unit that discharges ink (a liquid) onto the recording medium M, and a platen 18 as a recording medium support that supports the recording medium M being conveyed. The head unit 60 includes multiple liquid discharge heads.

Each of the multiple liquid discharge heads discharges ink onto the recording medium M based on image data generated by the controller 50 to form an image on the recording medium M. The ink is a liquid containing a colorant, a solvent, and crystalline resin particles dispersed in the solvent. The crystalline resin changes the phase thereof and melts from a crystal to a liquid when heated above the melting point thereof. The platen 18 faces the head unit 60 and supports the lower surface (back surface) of the recording medium M supplied from the recording medium supply device 11. The platen 18 approaches and separates from the head unit 60 so as to keep the distance between the head unit 60 and the recording medium M constant.

The conveyance device 13 includes multiple conveyance rollers 19. The recording medium M is conveyed to the image forming device 12 by the rotation of the conveyance rollers 19 while being stretched between the conveyance rollers 19. The conveyance device 13 may include other conveyors such as a conveyance belt.

The drying device 14 includes a heating drum 71 that heats the recording medium M to dry the ink on the recording medium M. The heating drum 71 has a cylindrical shape and rotates while the recording medium M is wound around the outer circumferential surface thereof, and a heating source such as a halogen heater is disposed inside the heating drum 71. In addition to a contact heating unit such as the heating drum 71, a non-contact heating unit such as a hot air generating device that blows hot air to the recording medium M can be used as a heating unit to heat the recording medium M.

The recording medium collection device 15 includes a collection roller 72 that winds and collects the recording medium M, and a tension adjustment mechanism 73 that adjusts the tension to be applied to the recording medium M. The collection roller 72 is rotatable in the direction indicated by the arrow illustrated in FIG. 7, and the recording medium M is wound in a roll-like shape around the collection roller 72 as the collection roller 72 rotates. The tension adjustment mechanism 73 includes multiple rollers, like the tension adjustment mechanism 17 of the recording medium supply device 11. Some of the multiple rollers move to adjust the tension of the recording medium M, and the recording medium M is wound up by the collection roller 72 with a constant tension.

As illustrated in FIG. 8, the controller 50 includes an information processing device such as a personal computer (PC). The controller 50 generates the image data to be formed on the recording medium M, and controls various operations of the recording medium supply device 11, the image forming device 12, the conveyance device 13, the drying device 14, and the recording medium collection device 15. For example, the controller 50 controls the temperatures of the heating source that heats the heating drum 71, in addition to the speeds of rotation of the supply roller 16, the collection roller 72, and the conveyance rollers 19.

FIG. 9 is a plan view of an example configuration of the head unit.

In the example illustrated in FIG. 9, the head unit 60 includes two head modules 70. The transverse direction (the direction Y indicated by arrow Y) of each head module 70 is aligned with a conveyance direction A of the recording medium M indicated by arrow A, and the longitudinal direction (the direction X indicated by arrow X) is aligned with a direction orthogonal to the conveyance direction A. As illustrated in FIG. 9, the “longitudinal direction” of each head module 70 means the longitudinal direction (the direction X indicated by arrow X) in which the head module 70 extends in one direction when viewed in a direction orthogonal to a nozzle face 2a through which the multiple nozzles 3 (see FIG. 2) are exposed. The “transverse direction” of each head module 70 means a direction (the direction Y indicated by arrow Y) orthogonal to the longitudinal direction of the head module 70 when viewed in the direction orthogonal to the nozzle face 2a. The longitudinal direction (the direction X) and the transverse direction (the direction Y) are also the longitudinal direction and the transverse direction of the nozzle faces 2a of the nozzle plate 2, respectively. The “longitudinal direction” and the “transverse direction” of the head module 70 described in the following description have the same meanings. In the present embodiment, the longitudinal direction (the direction X) is orthogonal to the conveyance direction A of the recording medium M, and the transverse direction Y is parallel to the conveyance direction A of the recording medium M. However, the transverse direction may be orthogonal to the conveyance direction A, and the longitudinal direction may be parallel to the conveyance direction A.

The head unit 60 illustrated in FIG. 9 is a so-called line head unit. When the recording medium M is conveyed to a position facing the head unit 60, the head unit 60 does not move and discharges ink from the multiple nozzles 3 of the liquid discharge heads 1 onto the recording medium M being conveyed to form an image on the recording medium M.

In addition to the line head unit, a so-called serial head unit that discharges ink while moving the liquid discharge heads in the main scanning direction (which is the width direction of the recording medium M) can be used.

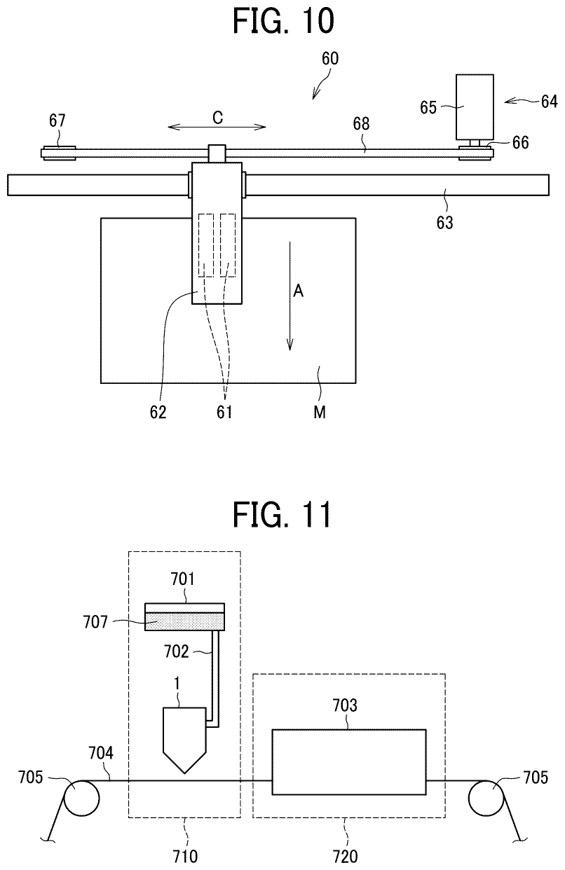

FIG. 10 is a view of an example configuration of the serial head unit 60. As illustrated in FIG. 10, the serial head unit 60 includes a carriage 62 on which liquid discharge heads 61 are mounted, a guide 63 (a guide rod) that guides the carriage 62 in the main scanning direction, which is the width direction C of the recording medium M indicated by arrow C, and a driver 64 that moves the carriage 62.

The driver 64 includes a motor 65 serving as a driving source, and a timing belt 68 looped around a drive pulley 66 and a driven pulley 67. As the motor 65 is driven, and the drive pulley 66 is rotated, the timing belt 68 circumferentially moves. Accordingly, the carriage 62 is moved in the main scanning direction along the guide 63. As the direction of rotation of the motor 65 is switched between one direction and the opposite direction, the carriage 62 reciprocates in the main scanning direction.

In such a serial head unit 60, the liquid discharge heads 61 discharge ink in response to image signals while the carriage 62 moves in the main scanning direction. In this manner, an image for one line is formed on the recording medium M that is not moving. The reciprocal movement of the carriage 62 and the discharge of the ink are repeatedly performed while the recording medium M is intermittently moved by a predetermined amount in the conveyance direction A of the recording medium M indicated by arrow A in FIG. 10. In this manner, an image is gradually formed on the recording medium M.

As a liquid discharge apparatus including the liquid discharge heads or the head module, apparatuses that manufacture electrodes and electrochemical elements will be described below with reference to FIG. 11. FIG. 11 is a schematic diagram of an example of an electrode manufacturing apparatus according to the present embodiment. The electrode manufacturing apparatus is an apparatus for manufacturing an electrode including a layer containing an electrode material by discharging a liquid composition by means of a head module including liquid discharge heads, or is an electric circuit manufacturing apparatus for manufacturing an electric circuit including an electrode.

A discharge device in the electrode manufacturing apparatus illustrated in FIG. 11 is a head module according to the present embodiment. As a liquid composition is discharged from the discharge heads of the head module, the liquid composition is applied onto the target object, and a liquid composition layer is formed. The target object (hereinafter also referred to as the “discharge target”) is not limited to any particular object, and may be selected as appropriate depending on the intended purpose, as long as the target object is an object on which a layer containing an electrode material can be formed. Examples of the target object include an electrode substrate (a current collector), an active material layer, and a layer containing a solid electrode material. Alternatively, the target object may be an electrode mixture layer containing an active material on an electrode substrate (a current collector). The discharge device and the discharge process may be a device and a process for forming a layer containing an electrode material by directly discharging a liquid composition, as long as the layer containing an electrode material can be formed on the discharge target (target object). The discharge device and the discharge process may be a device and a process for forming a layer containing an electrode material by indirectly discharging a liquid composition.

Other configurations included in an apparatus for manufacturing an electrode mixture layer are not limited to any particular ones, and may be selected as appropriate depending on the intended purpose, as long as the effects of the present embodiment are not impaired. Other processes included in a method for manufacturing an electrode mixture layer are not limited to any particular processes, and may be selected as appropriate depending on the intended purpose, as long as the effects of the present embodiment are not impaired. For example, a heating device and a heating process are examples of a component and a process included in the apparatus and the method for manufacturing an electrode mixture layer.

The heating device included in the apparatus for manufacturing an electrode mixture layer is a device that heats the liquid composition discharged by the discharge device. The heating process included in the method for manufacturing an electrode mixture layer is a process of heating the liquid composition discharged in the discharge process. The liquid composition is heated to dry the liquid composition layer.

As an example of the electrode manufacturing apparatus, an electrode manufacturing apparatus for forming an electrode mixture layer containing an active material on an electrode substrate (a current collector) is described below. As illustrated in FIG. 11, the electrode manufacturing apparatus includes a discharge process device 710 and a heating process device 720. The discharge process device 710 performs a discharge process of applying a liquid composition onto a print base material 704 having the discharge target, to form a liquid composition layer. The heating process device 720 performs a process of heating the liquid composition layer to obtain an electrode mixture layer.

The electrode manufacturing apparatus includes a conveyor 705 that conveys the print base material 704. The conveyor 705 conveys the print base material 704 to the discharge process device 710 and the heating process device 720 in this order at a preset speed. The method for manufacturing the print base material 704 having the discharge target such as an active material layer is not limited to any particular method, and a known method can be selected as appropriate. The discharge process device 710 includes a liquid discharge head 1 that performs a process of applying a liquid composition 707 onto the print base material 704, a storage container 701 that stores the liquid composition 707, and a supply tube 702 that supplies the liquid composition 707 stored in the storage container 701 to the liquid discharge head 1.

The discharge process device 710 discharges the liquid composition 707 from the liquid discharge head 1 so that the liquid composition 707 is applied onto the print base material 704 to form a liquid composition layer in the form of a thin film.

The storage container 701 may be integrated with the apparatus that manufactures the electrode mixture layer, or may be detachable from the apparatus that manufactures the electrode mixture layer. The storage container 701 may be a container to be used to make an addition into a container integrated with the apparatus that manufactures the electrode mixture layer, or into a container detachable from the apparatus that manufactures the electrode mixture layer.

The storage container 701 that stably stores the liquid composition 707 and the supply tube 702 that stably supplies the liquid composition 707 can be used.

The heating process device 720 performs a solvent removal process of heating and removing the solvent remaining in the liquid composition layer. Specifically, the solvent that remains in the liquid composition layer is heated and dried by a heater 703 of the heating process device 720. Thus, the solvent is removed from the liquid composition layer. In this manner, the electrode mixture layer is formed. The heating process device 720 may perform the solvent removal process under reduced pressure.

The heater 703 is not limited to any particular heater, and may be selected as appropriate depending on the intended purpose.

For example, the heater 703 may be a substrate heater, an infrared (IR) heater, a hot air heater, or the like.

The heater 703 may be a combination of at least two of a substrate heater, an IR heater, and a hot air heater. A heating temperature and a heating time can be selected as appropriate depending on the boiling point of the solvent contained in the liquid composition 707 or the thickness of the formed film.

The electrode manufacturing apparatus according to the present embodiment is used to discharge the liquid composition onto a desired target point on the discharge target. The electrode mixture layer can be suitably used as one of the components of an electrochemical element. The components of the electrochemical element other than the electrode mixture layer are not limited to any particular components, and known components can be selected as appropriate. For example, the components other than the electrode mixture layer may be a positive electrode, a negative electrode, a separator, or the like.

By applying the liquid discharge head described above to a head module and the liquid discharge apparatus described above, the discharge speed and the amount of the liquid to be discharged can be increased. As described above, the liquid discharge apparatus to which the liquid discharge head is applied is not necessarily an inkjet printer that discharges ink as the liquid to form an image, and may be the above-described electrode manufacturing apparatus (an electric circuit manufacturing apparatus), and a three-dimensional object fabricating apparatus that discharges liquid to form a three-dimensional structure. By applying the liquid discharge head described above in these liquid discharge apparatuses, the liquid discharge speed and the amount of the liquid to be discharged can be increased.

Although the present embodiment has been described, the present embodiment is not limited to the above embodiment, and various modifications can be made to it without departing from the gist of the present embodiment.

In the present application, the liquid to be discharged is not limited to any particular liquid, as long as the liquid has a sufficient viscosity or surface tension to be discharged from a head (a liquid discharge head). However, the viscosity of the liquid is preferably not higher than 30 mPa·s under ordinary temperature and ordinary pressure, or by heating or cooling. Specific examples of such liquids include, but are not limited to, solutions, suspensions, and emulsions containing solvents (such as water and organic solvents), colorants (such as dyes and pigments), functionality imparting materials (such as polymerizable compounds, resins, and surfactants), biocompatible materials (such as DNA (deoxyribonucleic acid), amino acid, protein, and calcium), and/or edible materials (such as natural colorants). These liquids can be used as inkjet inks, surface treatment liquids, liquids for forming components of electric or luminous elements or electronic circuit resist patterns, and three-dimensional object forming material liquids.

A liquid discharge head (1) includes: a nozzle plate (2) having multiple nozzles (3); a channel substrate (32) having multiple pressure chambers (41) respectively communicating with the multiple nozzles (3), the multiple pressure chambers (41) arrayed in an array direction of the channel substrate (32); a diaphragm (33) facing the multiple pressure chambers (41); and a piezoelectric member (40) to vibrate the diaphragm (33) to discharge liquid in the multiple pressure chambers (41) from the multiple nozzles (3) in a discharge direction perpendicular to the array direction, wherein the piezoelectric member (40) includes: a first individual electrode (401) over the diaphragm in a stacking direction opposite to the discharge direction; a first piezoelectric body (421) over the first individual electrode (401) in the stacking direction; a first common electrode (411) over the first piezoelectric body (421) in the stacking direction; a second piezoelectric body (422) over the first common electrode (411) in the stacking direction; and a second individual electrode (402) over the second piezoelectric body (422) in the stacking direction, and the first common electrode (411) extends across the multiple pressure chambers (41) in the array direction.

The liquid discharge head further includes: multiple first piezoelectric bodies (421) including the first piezoelectric body (421) arrayed in the array direction, wherein the first common electrode (411) extends across the multiple first piezoelectric bodies (421) in the array direction.

The channel substrate (32) includes wall portions (32) partitioning the multiple pressure chambers (41), the first common electrode (411) includes: stack portions (411a) facing the multiple first piezoelectric bodies (421) at positions corresponding to the multiple pressure chambers (41) in the array direction; and bridges (411b) disposed over the diaphragm (33) at positions facing the wall portions (32) in the array direction.

The liquid discharge head further includes: multiple second piezoelectric bodies (422) including the second piezoelectric body (422) arrayed in the array direction, wherein the first common electrode (411) extends across the multiple second piezoelectric bodies (422) in the array direction.

The channel substrate (32) includes wall portions (32) partitioning the multiple pressure chambers (41), the first common electrode (411) includes: stack portions (411a) facing the multiple second piezoelectric bodies (422) at positions corresponding to the multiple pressure chambers (41) in the array direction; and bridges (411b) disposed over the diaphragm (33) at positions facing the wall portions (32) in the array direction.

The liquid discharge head further includes: multiple first individual electrodes (401) including the first individual electrode (401); and multiple second individual electrodes (402) including the second individual electrode (402); and the multiple first individual electrodes and the multiple second individual electrodes are respectively disposed at positions corresponding to the multiple pressure chambers (41) in the array direction.

The first common electrode (411) includes: stacked portions (411a) disposed over the multiple first piezoelectric bodies (421), respectively; and bridges (411b): connecting the stacked portions; and disposed at positions between each of the multiple first individual electrodes in the array direction.

The piezoelectric member (40) includes an m-th piezoelectric unit including: a (2m−1)th individual electrode (401); a (2m−1)th piezoelectric body (421) over the (2m−1)th individual electrode in the stacking direction; an m-th common electrode (411) over the (2m−1)th piezoelectric body in the stacking direction; a 2m-th piezoelectric body (422) over the m-th common electrode in the stacking direction; and a 2m-th individual electrode (402) over the 2m-th piezoelectric body in the stacking direction, where m represents a natural number m=1, . . . , n, and n represents an integer of 2 or greater, and the piezoelectric member (40) further includes first to n-th piezoelectric units (400A, 400B) in the stacking direction of the piezoelectric member.

The piezoelectric member (40) includes an m-th piezoelectric unit including: a (2m−1)th piezoelectric body (421); an m-th common electrode (411) over the (2m−1)th piezoelectric body in the stacking direction; a 2m-th piezoelectric body (422) over the m-th common electrode in the stacking direction; and an (m+1)th individual electrode (402) over the 2m-th piezoelectric body in the stacking direction, where m represents a natural number m=1, . . . , n, and n represents an integer of 2 or greater, and the piezoelectric member (40) further includes: a first individual electrode (401); and first to n-th piezoelectric units, in the stacking direction of the piezoelectric member.

The m-th common electrode and a (m+1)th common electrode are electrically connected in at least any one of the m-th piezoelectric units.

A liquid discharge apparatus includes the liquid discharge head.

An inkjet printer includes the liquid discharge apparatus to discharge the liquid including an ink.

A three-dimensional fabricating apparatus includes the liquid discharge apparatus.

An electric circuit manufacturing apparatus includes the liquid discharge apparatus to discharge a conductive liquid.

The term “liquid” includes not only ink but also paint, a pretreatment liquid, a binder, and an overcoat liquid.

In the present application, a “liquid discharge apparatus” is an apparatus that includes a carriage including liquid discharge heads, and discharges liquid by driving the liquid discharge heads. The term “liquid discharge apparatus” used herein includes not only apparatuses that discharge liquid onto a recording medium to which the liquid can adhere, but also apparatuses that discharge the liquid into gas (air) or liquid.

The “liquid discharge apparatus” may include devices to feed, convey, and eject the material to which liquid can adhere. The liquid discharge apparatus may further include a pretreatment apparatus and a post-treatment apparatus.

The “liquid discharge apparatus” may be, for example, an image forming apparatus that forms an image on a paper sheet by discharging ink, or a three-dimensional object fabricating apparatus that discharges a fabricating liquid onto a powder layer in which a powder material is formed in layers to form a three-dimensional object.

The term “liquid discharge apparatus” is not limited to an apparatus that discharges liquid to visualize meaningful images, such as letters or figures. For example, the liquid discharge apparatus may be an apparatus that forms patterns having no meaning, or an apparatus that fabricates three-dimensional images.

The above-described term “medium to which liquid can adhere” means a medium to which liquid adheres at least temporarily, a medium to which liquid adheres and is fixed, or a medium into which liquid adheres and permeates. The medium to which liquid can adhere corresponds to the recording medium in the above embodiment. Examples of the “medium to which liquid can adhere” include recording media, such as paper sheets, recording paper, recording sheets of paper, film, and cloth, electronic components such as electronic substrates and piezoelectric elements, and media such as powder layers, organ models, and testing cells. The “medium to which liquid can adhere” includes any material to which liquid can adhere, unless particularly limited.

Examples of the “medium to which liquid can adhere” include any materials to which liquid can adhere even temporarily, such as paper, threads, fibers, fabrics, leather, metals, plastic, glass, wood, and ceramic.

Examples of the “liquid discharge apparatus” further include: a treatment liquid applying apparatus that discharges a treatment liquid onto a sheet to apply the treatment liquid to the surface of the sheet, for the purpose of reforming the surface of the sheet; and an injection granulation apparatus that injects a composition liquid containing a raw material dispersed in a solution, through multiple nozzles to granulate fine particles of the raw material.

The terms “image formation”, “recording”, “printing”, “image printing”, and “fabricating” used herein may be used synonymously with each other.

According to the present embodiment, the discharge speed and the amount of the liquid to be discharged can be increased.

Aspects of the present embodiment are as follows, for example.

Aspect 1

According to Aspect 1, a liquid discharge head includes:
a nozzle that discharges liquid;
multiple pressure chambers communicating with the nozzle; and
a piezoelectric member that causes pressure fluctuation in the pressure chamber,
the piezoelectric member including a first individual electrode, a first piezoelectric body, a first common electrode, a second piezoelectric body, and a second individual electrode that are stacked in order from a side of the pressure chambers in a stacking direction of the piezoelectric member, and
the first common electrode is disposed over multiple the pressure chambers as viewed in the stacking direction of the piezoelectric member.

Aspect 2

According to Aspect 2, in the liquid discharge head of Aspect 1, the second piezoelectric body includes multiple second piezoelectric bodies, and the first common electrode is provided over an entire region of the multiple second piezoelectric bodies, viewed in the stacking direction of the piezoelectric member.

Aspect 3

According to Aspect 3, in the liquid discharge head of Aspect 2, the first common electrode is provided over entire regions of all the second piezoelectric bodies, when viewed in the stacking direction of the piezoelectric member.

Aspect 4

According to Aspect 4, in the liquid discharge head of any one of Aspects 1 to 3,
the first individual electrode includes multiple first individual electrodes, and the second individual electrode includes multiple second individual electrodes, and
each of the first individual electrodes and each of the second individual electrodes are provided for the pressure chambers and face each other, when viewed in the stacking direction of the piezoelectric member.

Aspect 5

According to Aspect 5, in the liquid discharge head of Aspect 4,
the first common electrode includes stacked portions that are stacked on the first piezoelectric body, and a bridge connecting the stacked portions, and,
in the stacking direction of the piezoelectric member, the bridge is provided at a position where the first individual electrode is provided.

Aspect 6

According to Aspect 6, in the liquid discharge head of any one of Aspects 1 to 5,
m represents a natural number m=1, . . . , n, and n represents an integer of 2 or greater,
an m-th piezoelectric unit includes a (2m−1)th individual electrode, a (2m−1)th piezoelectric body, an m-th common electrode, a 2m-th piezoelectric body, and a 2m-th individual electrode that are stacked in order from a side of the pressure chambers, in the stacking direction of the piezoelectric member, and
the piezoelectric member includes first to n-th piezoelectric units in the stacking direction of the piezoelectric member.

Aspect 7

According to Aspect 7, in the liquid discharge head of any one of Aspects 1 to 5,
m represents a natural number m=1, . . . , n, and n represents an integer of 2 or greater,
an m-th piezoelectric unit includes a (2m−1)th piezoelectric body, an m-th common electrode, a 2m-th piezoelectric body, and an (m+1)th individual electrode that are stacked in order from a side of the pressure chambers, in the stacking direction of the piezoelectric member, and
the piezoelectric member includes a first individual electrode and first to n-th piezoelectric units in order from the side of the pressure chamber, in the stacking direction of the piezoelectric member.

Aspect 8

According to Aspect 8, in the liquid discharge head of Aspect 7, in at least any one of the m-th piezoelectric units, the m-th common electrode and the (m+1)th common electrode are electrically connected.

Aspect 9

According to Aspect 9, a liquid discharge apparatus includes the liquid discharge head of any one of Aspects 1 to 8.

Aspect 10

According to Aspect 10, the liquid discharge apparatus of Aspect 9 is an inkjet printer that discharges ink as the liquid.

Aspect 11

According to Aspect 11, the liquid discharge apparatus of Aspect 9 is a three-dimensional object fabricating apparatus.

Aspect 12

According to Aspect 12, the liquid discharge apparatus of Aspect 9 is an electric circuit manufacturing apparatus that discharges a conductive liquid.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A liquid discharge head comprising:
a nozzle plate having multiple nozzles;
a channel substrate having multiple pressure chambers respectively communicating with the multiple nozzles,
the multiple pressure chambers arrayed in an array direction;
a diaphragm facing the multiple pressure chambers; and
a piezoelectric member to vibrate the diaphragm to discharge liquid in the multiple pressure chambers from the multiple nozzles,
wherein the piezoelectric member includes:
a first individual electrode over the diaphragm in a stacking direction opposite to the discharge direction;
a first piezoelectric body over the first individual electrode in the stacking direction;
a first common electrode over the first piezoelectric body in the stacking direction;
a second piezoelectric body over the first common electrode in the stacking direction; and
a second individual electrode over the second piezoelectric body in the stacking direction, and
the first common electrode extends across the multiple pressure chambers in the array direction.

2. The liquid discharge head according to claim 1, further comprising:
multiple first piezoelectric bodies including the first piezoelectric body arrayed in the array direction,
wherein the first common electrode extends across the multiple first piezoelectric bodies in the array direction.

3. The liquid discharge head according to claim 2,
wherein the channel substrate includes wall portions partitioning the multiple pressure chambers,
the first common electrode includes:
stack portions facing the multiple first piezoelectric bodies at positions corresponding to the multiple pressure chambers in the array direction; and
bridges disposed over the diaphragm at positions facing the wall portions in the array direction.

4. The liquid discharge head according to claim 1, further comprising:
multiple second piezoelectric bodies including the second piezoelectric body arrayed in the array direction,
wherein the first common electrode extends across the multiple second piezoelectric bodies in the array direction.

5. The liquid discharge head according to claim 4,
wherein the channel substrate includes wall portions partitioning the multiple pressure chambers,
the first common electrode includes:
stack portions facing the multiple second piezoelectric bodies at positions corresponding to the multiple pressure chambers in the array direction; and
bridges disposed over the diaphragm at positions facing the wall portions in the array direction.

6. The liquid discharge head according to claim 2, further comprising:
multiple first individual electrodes including the first individual electrode; and
multiple second individual electrodes including the second individual electrode; and
the multiple first individual electrodes and the multiple second individual electrodes are respectively disposed at positions corresponding to the multiple pressure chambers in the array direction.

7. The liquid discharge head according to claim 6,
wherein the first common electrode includes:
stacked portions disposed over the multiple first piezoelectric bodies, respectively; and
bridges:
connecting the stacked portions; and
disposed at positions between each of the multiple first individual electrodes in the array direction.

8. The liquid discharge head according to claim 1,
wherein the piezoelectric member includes an m-th piezoelectric unit including:
a (2m−1)th individual electrode;
a (2m−1)th piezoelectric body over the (2m−1)th individual electrode in the stacking direction;
an m-th common electrode over the (2m−1)th piezoelectric body in the stacking direction;
a 2m-th piezoelectric body over the m-th common electrode in the stacking direction; and
a 2m-th individual electrode over the 2m-th piezoelectric body in the stacking direction,
where m represents a natural number m=1, . . . , n, and n represents an integer of 2 or greater, and
the piezoelectric member further includes first to n-th piezoelectric units in the stacking direction of the piezoelectric member.

9. The liquid discharge head according to claim 1,
wherein the piezoelectric member includes m-th piezoelectric units including:
a (2m−1)th piezoelectric body;
an m-th common electrode over the (2m−1)th piezoelectric body in the stacking direction;
a 2m-th piezoelectric body over the m-th common electrode in the stacking direction; and
an (m+1)th individual electrode over the 2m-th piezoelectric body in the stacking direction,
where m represents a natural number m=1, . . . , n, and n represents an integer of 2 or greater, and
the piezoelectric member further includes:
a first individual electrode; and
first to n-th piezoelectric units,
in the stacking direction of the piezoelectric member.

10. The liquid discharge head according to claim 9,
wherein the m-th common electrode and a (m+1)th common electrode are electrically connected in at least any one of the m-th piezoelectric units.

11. A liquid discharge apparatus comprising the liquid discharge head according to claim 1.

12. An inkjet printer comprising the liquid discharge apparatus according to claim 11 to discharge the liquid including an ink.

13. A three-dimensional fabricating apparatus comprising the liquid discharge apparatus according to claim 11.

14. An electric circuit manufacturing apparatus comprising the liquid discharge apparatus according to claim 11 to discharge a conductive liquid.
